(19) United States
(12) Patent Application Publication
(10) Pub. No.: US 2010/0300508 A1
(43) Pub. Date: Dec. 2, 2010

(54) PHOTOVOLTAIC SYSTEM

(76) Inventors: Robert Maier, Passau (DE); Paul Victorin, Tiefenbach (DE)

Correspondence Address: INTELLECTUAL PROPERTY GROUP;FREDRIKSON & BYRON, P.A., 200 SOUTH SIXTH STREET, SUITE 4000, MINNEAPOLIS, MN, 55402, US

(21) Appl. No.: 12/668,254

(22) PCT Filed: Jul. 9, 2008
(86) PCT No.: PCT/DE08/01114

§ 371 Date: Jul. 17, 2010

(30) Foreign Application Priority Data
Jul. 11, 2007 (DE) 10 2007 032 605.1

(51) Int. Cl. H01L 31/042

(52) U.S. Cl. 136/244

(57) ABSTRACT

The present invention relates to a photovoltaic installation having at least one photovoltaic element, in particular having a plurality of photovoltaic elements which are electrically connected to one another, as well as electrical connecting lines for providing electric current.

The present invention relates to a photovoltaic installation having at least one photovoltaic element, in particular having a plurality of photovoltaic elements which are electrically coupled to one another, and having electrical connecting lines for providing electric current.

Photovoltaic installations such as these are known from the prior art and are used to produce electrical energy by conversion of solar radiation energy in many ways. Known arrangements provide a multiplicity of individual photovoltaic modules which, for example, can be installed and grouped on building roofs, on facades or on open-air areas. The individual modules are generally connected in series in groups, as a result of which the electrical DC voltage which is generally produced nowadays can then if required be passed to an inverter, for example before feeding into a public electrical grid system, or can also be fed into a public electrical grid system or can be provided for in-house consumption, as required, directly or possibly after voltage conversion or conversion in an electric motor with a generator, or possibly after temporary storage. It has now also become possible to produce AC voltage by means of specific photovoltaic modules.

In the event of damage or a fault, in particular in the event of fires, the electrical voltage values provided by the installation may, however, lead to serious problems. Specifically, it has now become possible for photovoltaic installations according to the prior art to draw power from the grid system by operation of specific switch disconnectors. This DC (i.e., direct current) disconnection is generally provided only at the junction to the inverter. For example, if a fire occurs, the fire service can render at least part of the building electrically non-live by means of this disconnection. However, this does not apply to the photovoltaic modules and the electrical lines to the DC switch disconnectors. They nevertheless remain live. In the case of a photovoltaic roof, the entire roof and the lines, modules, connecting boxes or else further components—at least during the daytime—are live at voltages of up to several hundred volts (generally DC voltage). This situation is effectively completely unchanged when the DC switch disconnector is opened.

The presence of high voltages (for example 900 volts in the case of relatively large photovoltaic installations) in the area of the photovoltaic installations results in a lethal hazard when electrically conductive parts are touched (for example exposed connecting lines without insulation between the photovoltaic modules). This creates major hazards to the fire service personnel when extinguishing a fire with extinguishing water in the area of photovoltaic installations, in particular photovoltaic modules.

This problem has been raised in DE 20 2006 007 613 U1 which mainly provides thermal circuit disconnection (at about 100-200° C.) irreversibly. However, in fact, such thermal circuit disconnection is completely inadequate because there must already be a fire in the area of the modules to allow such “protection” to operate at all. It is not possible to tell visually whether the protective function has been activated. Only when the flames are already passing over the modules can it be assumed, possibly, that the protective function has been activated. The thermal circuit disconnection cited in the cited document is carried out only passively, and cannot be initiated actively.

The object of the present invention is to overcome the disadvantages of the photovoltaic installations from the prior art.

According to the invention, this object is achieved by a photovoltaic installation having at least one photovoltaic element, in particular also having a plurality of photovoltaic elements which are electrically coupled to one another, and having electrical connecting lines for providing electric current, which is characterized in that the current flow and/or the voltage and/or the electrical connection can be controlled on at least one photovoltaic element and/or within at least one photovoltaic element and/or between a plurality of photovoltaic elements.

By way of example, with the photovoltaic installation according to the invention, it is thus possible to completely remove potentially lethal voltage values, or switch them to be non-live, when required, for example in an emergency. This allows all the electrically conductive parts of the photovoltaic installation to be made touch-safe. In the photovoltaic installation according to the invention it is also possible without any problems to extinguish fires with the use of extinguishing water in all parts of the installation.

In general, the photovoltaic installation according to the invention has a plurality of photovoltaic elements which are electrically coupled to one another. The photovoltaic elements are preferably photovoltaic modules. However, it is also feasible for an entire photovoltaic installation to comprise a single photovoltaic element. It is also feasible for the individual photovoltaic elements to be photovoltaic roof tiles. The photovoltaic elements may also be surfaces which are painted with photovoltaic paint or are coated with a photovoltaic coating, in particular also possibly with additional components. Furthermore, it is feasible for the photovoltaic elements to be webs which are provided with photovoltaically acting elements, can be adhesively bonded in place and which are possibly also, in particular, elastic or do not have a smooth surface. In general, a photovoltaic element means an element which produces electric current, generally by means of the photoelectric effect, when electromagnetic radiation or photons (light) is or are incident on it. This electric current is in general passed from one element to another through a respective connecting box on the lower face of the element via the connecting lines. Every other connection version is also intended to be included and covered here.

In one preferred embodiment of the photovoltaic installation according to the invention, this installation has a plurality of photovoltaic elements which are electrically coupled to one another, wherein the current flow between at least two of the photovoltaic elements is preferably controllable by means of an interruption device. Controllable means that the current flow can be entirely or partially interrupted or reduced—also reversibly—or the applied voltage can be reduced, or controlled or switched off within a photovoltaic element. Such control of the current flow and/or of the voltage on or in one or between two photovoltaic elements or within a photovoltaic element also means that the current and voltage on connecting lines between these two photovoltaic elements are considerably reduced, and in particular are also rendered completely non-live, and can thus be made as touch-safe as possible.

In one specific embodiment of the photovoltaic installation according to the invention, the photovoltaic elements, which in particular are coupled in series, can be electrically disconnected from one another and connected again alternately in groups.

In one preferred embodiment of the photovoltaic installation according to the invention, all of the photovoltaic elements, in particular, are coupled in series and can be electrically disconnected from one another and coupled again alternately. When required, it is therefore possible to electrically disconnect the current flow between all of the photovoltaic elements in a photovoltaic installation, thus allowing all the electrical connecting lines between the individual photovoltaic elements to be made essentially non-live. In consequence, as far as possible all the elements of the photovoltaic installation can be made safe to touch.

Preferably, control is provided via at least one remotely controllable switch, whose operation makes it possible in particular to interrupt and reproduce the current flow between the photovoltaic elements. The switch is preferably controlled without the use of wires. The control can be provided, for example, by radio, light, electrically, etc.

By way of example, the switch may be a magnetically operated switch.

It is also possible to use lines to or between the photovoltaic elements for control, in particular also connecting lines. Active self-activation is also possible, preferably, for example, by means of sensors and microprocessor control.

Advantageously, at least one photovoltaic element can at least partially be controlled, in particular switched off, individually. For the first time, this means that it is completely impossible for dangerous currents to flow out of the photovoltaic elements. For example, individual photovoltaic elements can be switched off by providing one or more switches in the photovoltaic element, by means of which the circuit within a photovoltaic element can be interrupted.

A further possible way to switch off individual photovoltaic elements is to produce short circuits in the individual photovoltaic elements. These short circuits can likewise be made and broken again by controllable switches.

In a further embodiment of the photovoltaic installation according to the invention, the wafers within a photovoltaic element can at least partially be controlled, in particular switched off, individually or overall. This likewise makes it possible to switch off individual photovoltaic elements.

In a further embodiment of the invention, the photovoltaic elements can be mechanically, physically, biologically, chemically or biochemically isolated from the energy source, in particular the sun, in particular also with respect to reducing the effectiveness of the photoelectric effect in the photovoltaic elements. For example, the photovoltaic elements or parts of them, in particular also the wafers, may be shadowed mechanically or in electrical/electromagnetic/crystal-technical ways, and/or biological or chemical or biochemical and/or optical ways (embodiment variants: with liquid crystals, “louvres”, grids, shutters, lens system etc.). The result is photovoltaic control even down to the photovoltaic elements being switched off, in particular by at least partial reduction in the power from the light or energy source or by reducing the light intensity or power acting on the photovoltaically relevant components.

As already mentioned above, the photovoltaic elements are preferably photovoltaic modules.

Further features of the invention will become evident from the following description of preferred embodiments of the invention in conjunction with the drawings and the dependent claims. In this case, each of the individual features may be implemented in their own right or in combination with one another.

In the drawings:

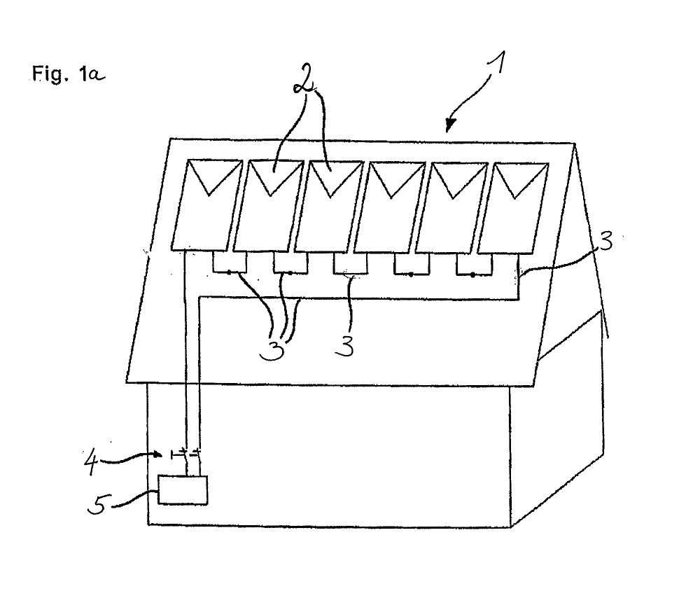

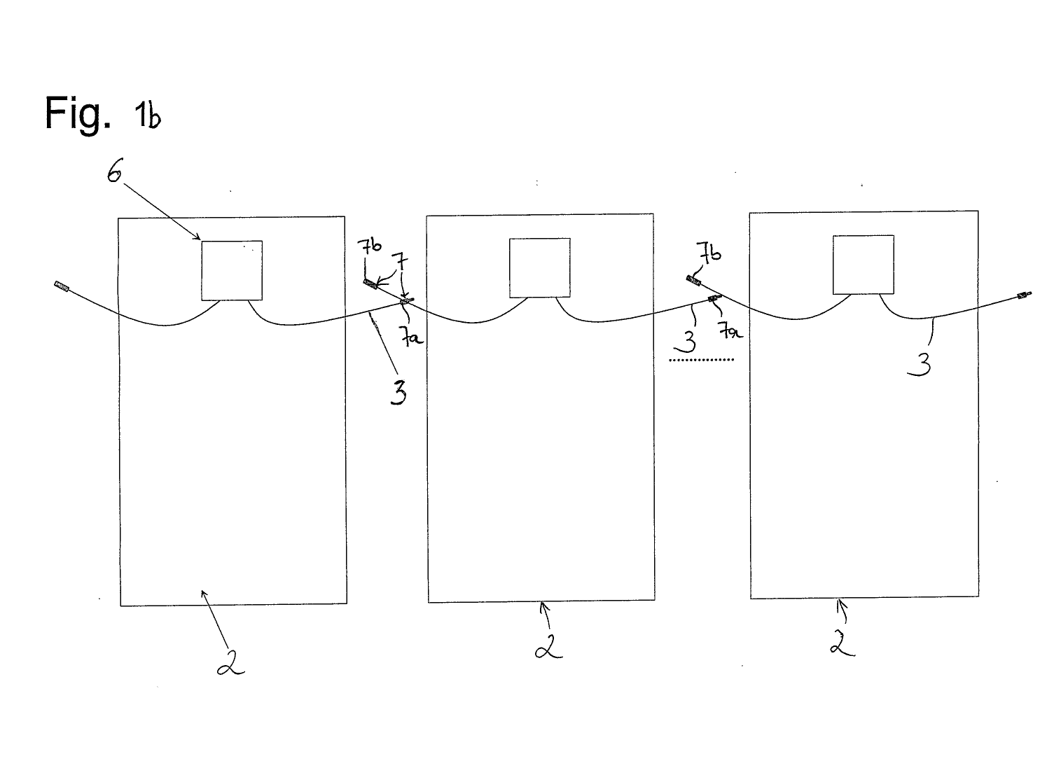

FIG. 1a shows a schematic illustration of the basic design of a photovoltaic installation from the prior art;

FIG. 1b shows an illustration of a conventional arrangement of photovoltaic elements according to the current prior art;

FIG. 1c shows a circuit diagram of a photovoltaic installation from the prior art;

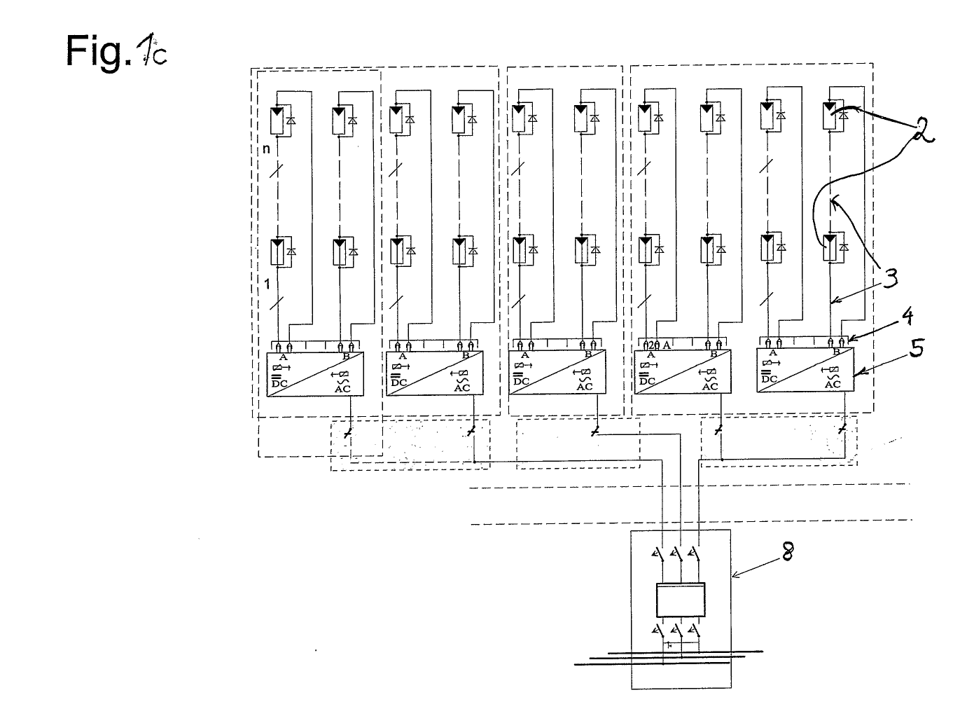

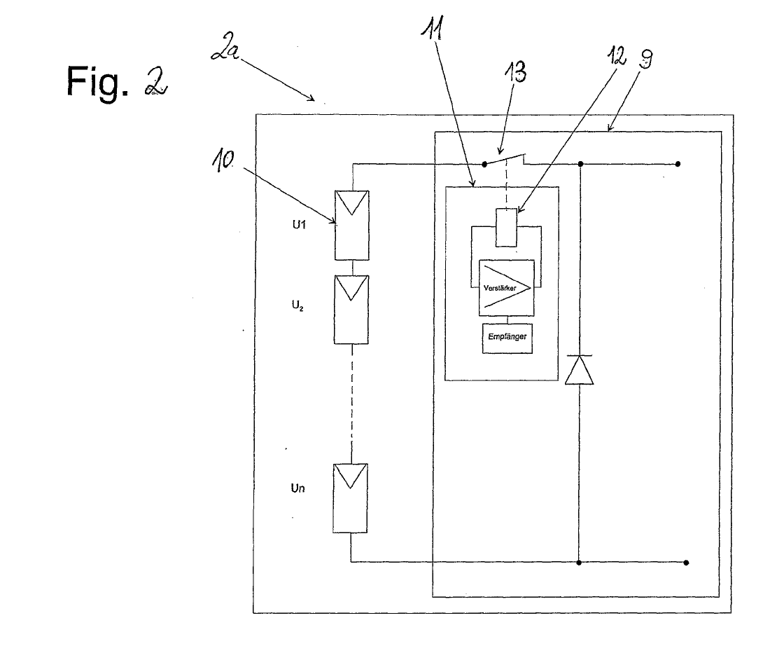

FIG. 2 shows a schematic circuit diagram of a photovoltaic module of one embodiment of a photovoltaic installation according to the invention;

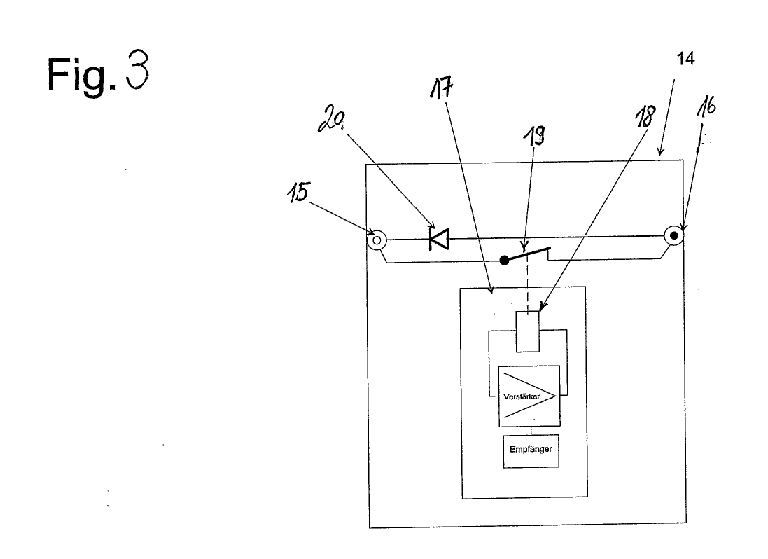

FIG. 3 shows a schematic circuit diagram of a photovoltaic element connecting box for use with a further embodiment of the photovoltaic installation according to the invention;

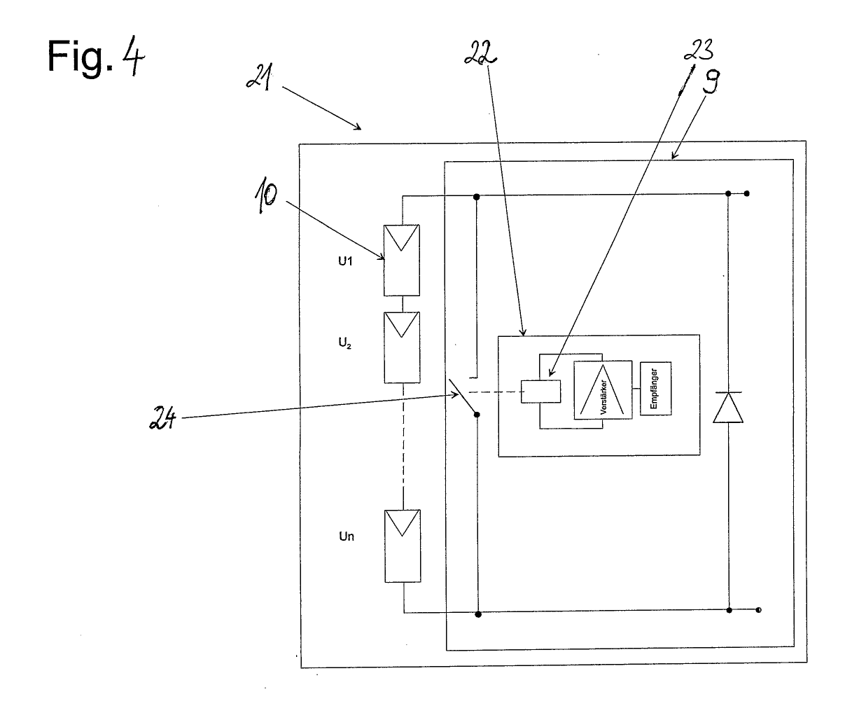

FIG. 4 shows a schematic circuit diagram of a photovoltaic module of a further embodiment of the photovoltaic installation according to the invention.

FIG. 1a shows a schematic illustration of a basic design of a photovoltaic installation 1 from the prior art, which is located on the roof of a residential building. The photovoltaic installation is formed from individual photovoltaic modules 2 which are connected in series in groups (as so-called “string”), with a plurality of groups possibly being connected in parallel (not illustrated). The individual photovoltaic modules 2 are electrically connected via electrical connecting lines 3. The figure also shows an electrical junction point 4 which, for example, may be a switch box, a so-called DC voltage switch disconnector (DC switch disconnector) or the like at which the entire DC voltage produced by the photovoltaic modules 2 is available.

The DC voltage produced by the installation 1 is normally passed to an inverter 5, which is required for feeding into a public electrical grid system, in order that the voltage can be changed to the values required for the grid system—typically 230 volts and 50 Hertz. In the event of an emergency, for example in the event of a fire, the photovoltaic installation can be disconnected from the electrical grid system at the DC switch disconnector. However, disconnection of the photovoltaic installation at the DC switch disconnector 4 does not result in voltage being removed from the conductive elements (for example the connecting lines 3) of the photovoltaic installation 1. For example, voltages of several hundred volts may be present on the lines 3 between the photovoltaic modules 2 (depending on the number of series-connected photovoltaic modules 2). This, of course, results in major hazards to personnel, for example fire service personnel, who touch these parts. The present invention means that all parts of a photovoltaic installation can, when required, have hazardous electrical voltage values removed from them, possibly also reversibly. By way of example, this makes it possible to reliably prevent any hazard to firefighters when fires occur.

FIG. 1b shows a more detailed illustration of the photovoltaic modules 2 from FIG. 1. Each of the modules 2 has a connecting box 6 from which the connecting lines emerge. The individual connecting lines 3 can be connected via a plug 7 to a male connecting part 7a and a female connecting part 7b. The connecting lines 3 may also be used for signal transmission.

FIG. 1c shows a typical circuit diagram of a photovoltaic installation as is now conventional according to the current prior art. On the basis of the principle shown in FIGS. 1a and 1b, different strings of photovoltaic elements 2, in each case connected as shown in FIG. 1a and FIG. 1b, can be joined together—in this case interruptably by means of switch disconnectors 4, before being joined together at the inverter 5. For generally conventional photovoltaic installations nowadays, the inverter 5 converts the direct current which is generally produced by direct-current photovoltaic elements to alternating current, as is normally required for electrical loads or the grid connection to the public grid system. As is shown in the present installation, a plurality of inverters 5 can once again also be interconnected in a protected form before the current can be fed into the public electrical grid system, once again in a protected form, via the meter distribution box 8, or can be made available for electrical loads.

FIG. 2 shows a schematic circuit diagram illustration of a photovoltaic module 2a according to one embodiment of a photovoltaic installation according to the invention. In the same way as the photovoltaic module illustrated in FIG. 1b, the present photovoltaic module 2a also has a connecting box 9. The photovoltaic module 2a furthermore has a plurality of units of photoelectrically acting (photovoltaic) components, in this case so-called wafers 10. The photovoltaic module 2a furthermore has a control unit 11 with a receiver and amplifier for switching a relay 12. The control process can be carried out autonomously via sensors and integrated logic or mechanisms, or can be operated externally by means of transmitted signals. In the event of danger or when required, the photovoltaic element 2a can be electrically disconnected, as a result of which there is no longer any dangerous electrical hazard potential applied to the module from the outside (neither high voltage nor high electrical power). This is achieved by external or internal activation of the control unit 11, in which the relay 12 is operated, thus opening the switch 13 in the relay. The circuit within the module 2a is therefore interrupted.

This could also be done at the level of the individual components or one individual other component on or in the photovoltaic module. If the control is activated on the basis of an external signal, then this can be transmitted by radio or other signals. However, it is also possible to transmit signals via a power transmission path which can also be used for signal transmission (for example by inductive transmission via galvanically isolated components).

When the switch 13 interrupts the circuit within the photovoltaic module 2a, this also, of course, means that current can no longer flow from the photovoltaic module 2a to another photovoltaic module, as a result of which a connecting line between the photovoltaic module 2a and an adjacent photovoltaic module also carries no current.

FIG. 3 shows a schematic circuit diagram of an apparatus for interrupting the electrical connection between two photovoltaic modules, referred to in the following text as an isolating box 14. The isolating box 14 illustrated here makes it possible to equip already existing and installed photovoltaic installations according to the invention.

The isolating box 14 has connecting sockets 15 and 16 to which connecting lines can be connected, which each lead to one photovoltaic module. The isolating box 14 has a control unit 17 for switching a relay 18. The control can be carried out autonomously via sensors and integrated logic or mechanisms, or can be operated externally by means of transmitted signals. The electrical connection in the isolating box 14 can be disconnected by the switch in the relay 18. This interrupts the current flow between the photovoltaic modules which are connected to the isolating box via the connecting sockets 15 and 16. Furthermore, the isolating box 14 has a device 20 which despite line disconnection ensures, for example, that a signal can still be transmitted via the circuit, but significant power can no longer be transmitted, in particular no hazardous electrical power or voltage. As a variant, galvanic isolation and coupling are feasible by means of inductive elements, semiconductor circuits or other circuits with corresponding matching characteristics.

FIG. 4 shows a schematic circuit diagram of a photovoltaic module 21 of a further embodiment of a photovoltaic installation according to the invention. The photovoltaic module 21 also has a multiplicity of wafers 10. The photovoltaic module 21 likewise has a control unit 22 with an amplifier and receiver, which control unit 22 is likewise used for switching a relay 23, to be precise a switch 24 integrated in it. In the present embodiment variant, an internal short circuit can be produced in the photovoltaic module 21 by operation of the switch 24 (closing the switch), thus equalizing the potentials between the connections of the photovoltaic module 21. As a result, there can be no danger-relevant voltage, or else no disturbing voltage or voltage to be controlled, or current flowing, externally on the photovoltaic module 21. For example, this means that it is no longer possible to receive an electric shock by touching the external contacts of the photovoltaic module 21, because there is no longer any sufficient potential difference there, and the photovoltaic module has been internally short-circuited. The short circuit is activated analogously to the other embodiments and solutions by a switch 24 in the relay 23, by means of the control 22.

In all the embodiments, it is preferable for the control signal which is transmitted in particular by radio, light or electrically (generally electromagnetically) or which can be initiated internally by means of sensors etc. to have additional circuitry to protect the installation by means of residual current devices and asymmetric current switching associated with this, leading to tripping of the residual current devices. If the control (for example control unit 22 or 11) subsequently switches a relay, the switching process can be carried out on no-load, which means that the relay switching powers required are considerably less, because the circuit is already open at the time of switching.

It is self-evident that the described embodiments represent only examples of the principle of the present invention. Numerous further technical variants for implementation of the invention are possible. For example, the current can be interrupted in the area of the photovoltaic modules or in the area of the electrical lines which lead from the photovoltaic modules to the inverter, and this can be done by all feasible current interruption apparatuses.

When a photovoltaic installation according to the invention is switched off, the inverter is preferably first of all disconnected from the photovoltaic installation. By way of example, the individual photovoltaic modules are not switched off until this has been done. Disconnecting the inverter results in the closed circuit being interrupted first of all, and the individual modules have to carry considerably less current flow than if the circuit were to be closed. The modules therefore need not be switched off exactly at the same time, in order not to damage them.

1. Photovoltaic installation having at least one photovoltaic element, in particular having a plurality of photovoltaic elements which are electrically coupled to one another, as well as electrical connecting lines for providing electric current, wherein the current flow and/or the voltage and/or the electrical connection can be controlled at least one photovoltaic element and/or within at least one photovoltaic element and/or between a plurality of photovoltaic elements.

2. Photovoltaic installation according to claim 1, wherein the installation has a plurality of photovoltaic elements which are electrically connected to one another, wherein the current flow between at least two of the photovoltaic elements can preferably be controlled by means of an interruption device.

3. Photovoltaic installation according to claim 1, wherein the photovoltaic elements, which are in particular coupled in series, can be electrically disconnected from one another and coupled again alternately in groups.

4. Photovoltaic installation according to claim 1, wherein the photovoltaic elements, in particular, are coupled in series and can be electrically disconnected from one another and coupled again alternately.

5. Photovoltaic installation according to claim 1, wherein control is provided via at least one remotely controllable switch, whose operation makes it possible in particular to interrupt and reproduce the current flow between the photovoltaic elements.

6. Photovoltaic installation according to claim 5, wherein the switch is controlled without the use of wires.

7. Photovoltaic installation according to one of claim 5, wherein the switch is a magnetically operated switch.

8. Photovoltaic installation according to claim 1, wherein at least one photovoltaic element can at least partially be controlled, in particular switched off, individually.

9. Photovoltaic installation according to claim 8, wherein at least one photovoltaic element can at least partially be switched off individually by producing a short circuit.

10. Photovoltaic installation according to claim 1, wherein each of the photovoltaic elements have a wafer and the wafers within a photovoltaic element can at least partially be controlled, in particular switched off, individually or overall.

11. Photovoltaic installation according to claim 1, characterized in that the photovoltaic elements are photovoltaic modules (2, 2a, 21).

12. Photovoltaic installation according to claim 1, wherein the photovoltaic elements can be mechanically, physically, biologically, chemically or biochemically isolated from the energy source, in particular the sun, in particular also with respect to reducing the effectiveness of the photoelectric effect in the photovoltaic elements.

13. Photovoltaic installation according to claim 6 wherein the switch is a magnetically operated switch.
